(19) United States
(12) Patent Application Publication
(10) Pub. No.: US 2026/0271490 A1
(43) Pub. Date: Sep. 10, 2026

(54) LIGHT-EMITTING ELEMENT AND DISPLAY DEVICE

(71) Applicant: Sharp Display Technology Corporation, Kameyama City, Mie (JP)

(72) Inventors: Takahiro DOE, Sakai City, Osaka (JP); Yoshihiro UETA, Sakai City, Osaka (JP)

(21) Appl. No.: 19/112,025

(22) PCT Filed: Oct. 19, 2022
(86) PCT No.: PCT/JP2022/038897

§ 371 Date: Mar. 14, 2025

(51) Int. Cl. H10K 50/115; H10K 50/15

(52) U.S. Cl. CPC H10K 50/115; H10K 50/15

(57) ABSTRACT

A light-emitting element according to the disclosure includes a light-emitting layer, an anode, a cathode, and a function layer. The light-emitting layer is disposed between an anode and a cathode. The light-emitting layer includes a plurality of quantum dots and an inorganic matrix material with which filling is made between the plurality of quantum dots. The function layer is disposed between the anode and the cathode to be adjacent to the light-emitting layer. The function layer is formed of constituent elements identical to those of the inorganic matrix material and has a composition ratio different from a composition ratio of the inorganic matrix material.

### TECHNICAL FIELD

The disclosure relates to a light-emitting element, a display device, and a light-emitting element manufacturing method.

### BACKGROUND ART

In a light-emitting element including a light-emitting layer containing quantum dots as a light-emitting material, carriers may pass through the light-emitting layer without being injected into the quantum dots, whereby a reactive current is generated. The generation of the reactive current causes the deterioration of the quantum dots, a charge transport layer, and the like in addition to a decrease in light emission power efficiency of the light-emitting element, thereby raising a problem of a decrease in reliability of the light-emitting element. PTL 1 discloses a light-emitting element in which a light-emitting layer includes a plurality of quantum dots having shells with mutually different thicknesses, whereby carrier confinement in the quantum dots is improved.

### CITATION LIST

### Patent Literature

PTL 1: WO 2015/056750.

### SUMMARY

### Technical Problem

In the light-emitting element disclosed in PTL 1, since organic ligands are present between the quantum dots, it is difficult to raise the light emission power efficiency by reducing the reactive current flowing through between the quantum dots. In addition, the deterioration of the organic ligands brings about a problem of a decrease in reliability.

### Solution to Problem

A light-emitting element according to an aspect of the disclosure includes: an anode and a cathode; a light-emitting layer disposed between the anode and the cathode, and including a plurality of quantum dots and an inorganic matrix material with which filling is made between the plurality of quantum dots; and a function layer disposed between the anode and the cathode to be adjacent to the light-emitting layer, the function layer being formed of constituent elements identical to constituent elements of the inorganic matrix material and having a different composition ratio from a composition ratio of the inorganic matrix material.

### Advantageous Effects of Disclosure

According to an aspect of the disclosure, light emission power efficiency of a light-emitting element is improved.

### BRIEF DESCRIPTION OF DRAWINGS

FIG. 1 is a cross-sectional view illustrating a configuration of a light-emitting element according to an embodiment.

FIG. 2 is an example of a schematic band diagram of the light-emitting element illustrated in FIG. 1.

FIG. 3 is a cross-sectional view illustrating another configuration of the light-emitting element according to the embodiment.

FIG. 4 is an example of a schematic band diagram of the light-emitting element illustrated in FIG. 3.

FIG. 5 is a cross-sectional view illustrating another configuration of the light-emitting element according to the embodiment.

FIG. 6 is an example of a schematic band diagram of the light-emitting element illustrated in FIG. 5.

FIG. 7 is a cross-sectional view illustrating another configuration of the light-emitting element according to the embodiment.

FIG. 8 is an example of a schematic band diagram of the light-emitting element illustrated in FIG. 7.

FIG. 9 is a cross-sectional view illustrating another configuration of the light-emitting element according to the embodiment.

FIG. 10 is an example of a schematic band diagram of the light-emitting element illustrated in FIG. 9.

FIG. 11 is a cross-sectional view illustrating another configuration of the light-emitting element according to the embodiment.

FIG. 12 is an example of a schematic band diagram of the light-emitting element illustrated in FIG. 11.

FIG. 13 is a cross-sectional view illustrating another configuration of the light-emitting element according to the embodiment.

FIG. 14 is a flowchart illustrating a method for manufacturing the light-emitting element according to the embodiment.

FIG. 15 is a schematic cross-sectional view illustrating a method for forming a function layer by using a CBD method.

FIG. 16A is a schematic cross-sectional view illustrating a forming example of an inorganic matrix material.

FIG. 16B is a schematic cross-sectional view illustrating a forming example of an inorganic matrix material.

FIG. 17 is a schematic diagram illustrating an example of a configuration of a display device according to the present embodiment.

FIG. 18 is a cross-sectional view illustrating an example of a configuration of the display device according to the present embodiment.

### DESCRIPTION OF EMBODIMENTS

### First Embodiment

### Configuration of Light-Emitting Element

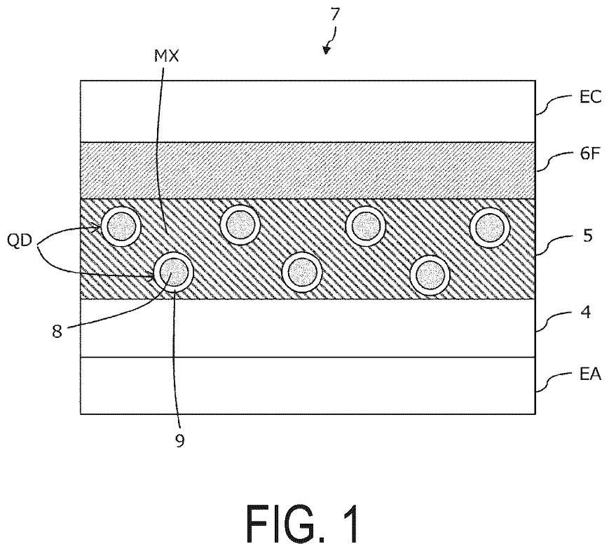

FIG. 1 is a cross-sectional view illustrating a configuration of a light-emitting element according to an embodiment. As illustrated in FIG. 1, a light-emitting element 7 according to the present embodiment includes: an anode EA and a cathode EC; a light-emitting layer 5 disposed between the anode EA and the cathode EC, and including a plurality of quantum dots QD and an inorganic matrix material MX, with which filling is made between the plurality of quantum dots QD; and a function layer 6F disposed between the anode EA and the cathode EC to be adjacent to the light-emitting layer 5, the function layer 6F being formed of constituent elements identical to constituent elements of the inorganic matrix material MX, and having a different composition ratio from a composition ratio of the inorganic matrix material MX. The function layer 6F and the inorganic matrix material MX may be chalcogenide metals of the same crystal type. The function layer 6F may be an electron transport layer (ETL) disposed between the cathode EC and the light-emitting layer 5. A hole transport layer (HTL) 4 may be disposed between the anode EA and the light-emitting layer 5.

In the light-emitting element 7, since the inorganic matrix material MX and the function layer 6F formed of the identical constituent elements are subjected to homo junction, a potential barrier between the function layer 6F and the inorganic matrix material MX becomes small. Thus, charge injection (for example, injection of electrons) from the function layer 6F into the light-emitting layer 5 is facilitated, and light emission power efficiency (power consumption-luminance characteristics of the light-emitting element) is improved.

Since the inorganic matrix material MX terminates surface defects of the quantum dots QD and reduces non-emitting recombination in the quantum dots QD, external luminous efficiency (EQE) is improved. Since the inorganic matrix material MX is excellent in durability as compared with a general organic ligand, the reliability of the light-emitting element 7 is enhanced.

As described above, the function layer 6F, which is a compound identical to the compound of the inorganic matrix material MX (the constituent elements are identical) but has a different composition from that of the inorganic matrix material MX, is adjacently formed on the light-emitting layer 5, whereby a voltage for carrier injection can be lowered while using the inorganic matrix material MX capable of being formed at a low temperature and having a low defect density (e.g., zinc sulfide or zinc selenide).

Each of the plurality of quantum dots QD may have a core 8, and may have a shell 9, whose constituent elements are identical to those of the inorganic matrix material MX. The composition ratio of the inorganic matrix material MX and the composition ratio of the shell 9 may be identical or may be different from each other. With this, the light-emission characteristics (voltage-luminance characteristics) can be exhibited at a lower voltage while maintaining the confinement effect by the shell 9.

Each of the function layer 6F and the inorganic matrix material MX may include a metal element and a nonmetal element, and the metal element may be zinc while the nonmetal element may be sulfur or selenium. The function layer 6F may include a hydroxyl group, and a metal-hydroxyl group bond may be included in the function layer 6F (details thereof will be described later).

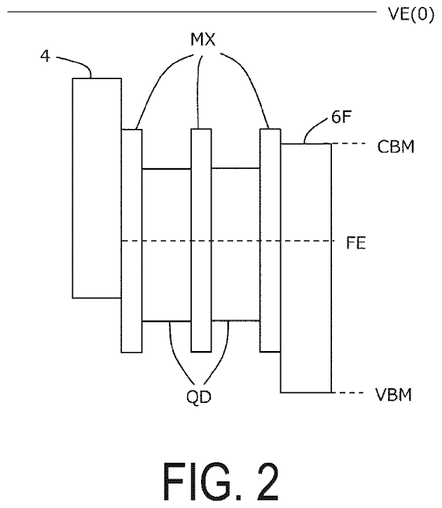

FIG. 2 is an example of a schematic band diagram of the light-emitting element illustrated in FIG. 1. Hereinafter, being close to the vacuum level VE (0 eV) is expressed as “being shallow”, and being far from the vacuum level VE (0 eV) is expressed as “being deep”. CBM is a conduction band minimum level, VBM is a valence band maximum level, a band gap is a difference between CBM and VBM, and FE is a Fermi level. As illustrated in FIG. 2, the band gap of the inorganic matrix material MX may be larger than the band gap of the plurality of quantum dots QD. The band gap of the quantum dot QD may be a band gap of the core, or may be a band gap of the shell.

In the case where the function layer 6F is the electron transport layer (ETL) disposed between the light-emitting layer 5 and the cathode EC, the CBM of the function layer 6F may be shallower than that of the plurality of quantum dots QD, and may be deeper than that of the inorganic matrix material MX. The CBM of the quantum dot QD may be the CBM of the core. With this, the quantity of electrons injected can be adjusted by adjusting the CBM of the function layer 6F, and since the CBM thereof is shallower than that of the quantum dot QD, an electron injection barrier from the function layer 6F (electron transport layer) into the light-emitting layer 5 is reduced, and the light emission power efficiency is enhanced. In addition, since the CBM of the function layer 6F is adjusted to be deeper than the CBM of the inorganic matrix material MX, electron injection into the inorganic matrix material MX is suppressed. As a result, a light-emitting region comes to be closer to the function layer 6F, and non-emitting recombination at the interface between the hole transport layer 4 and the light-emitting layer 5 may be suppressed. In the case of FIGS. 1 and 2, the CBM of the function layer 6F (ETL) may be deeper than that of the shell 9 of the quantum dot QD.

By controlling the Fermi level of the function layer 6F, a step-like potential can be formed, and the voltage for carrier injection (electron injection) may be lowered. The Fermi level can be controlled by, for example, controlling a zinc element proportion in zinc sulfide or zinc selenide; in a case where the zinc elements are excessive in quantity, n-type conductivity is obtained using a sulfur defect or a selenium defect as a donor. Accordingly, the function layer 6F (ETL) may have a larger zinc composition ratio than that of the inorganic matrix material MX. In a case where the function layer 6F (ETL) is zinc sulfide represented by ZnₓS (x>1), for example, the inorganic matrix material MX is zinc sulfide represented by Zn_{y}S (0<y<x). In a case where the function layer 6F (ETL) is zinc selenide represented by ZnₓSe (x>1), for example, the inorganic matrix material MX is zinc selenide represented by Zn_{y}Se (0<y<x).

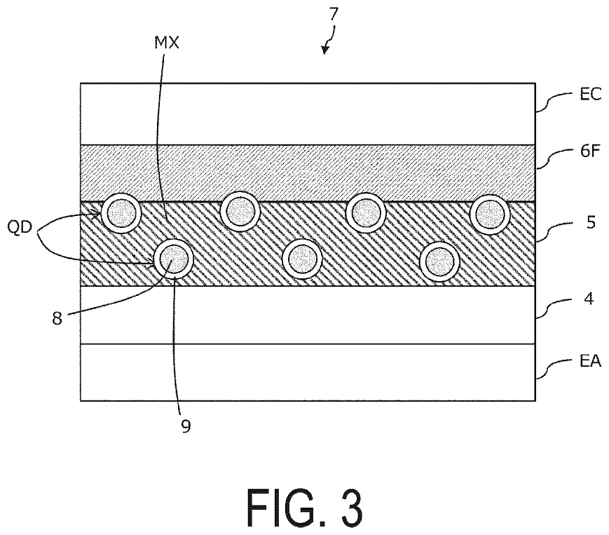

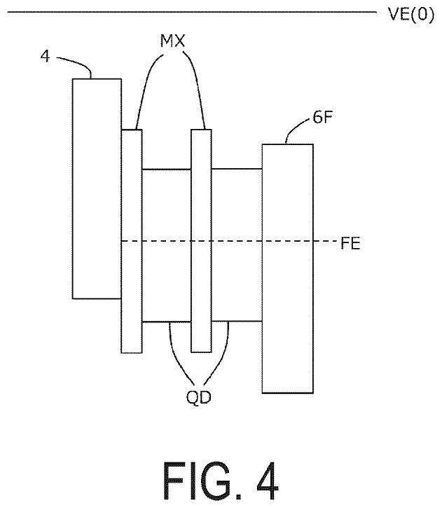

FIG. 3 is a cross-sectional view illustrating another configuration of the light-emitting element according to the embodiment. FIG. 4 is an example of a schematic band diagram of the light-emitting element illustrated in FIG. 3. As illustrated in FIG. 3, at least one of the plurality of quantum dots QD may be in contact with the function layer 6F. That is, the light-emitting layer 5 includes the quantum dot QD having a portion exposed from the inorganic matrix material MX, and the exposed portion is in contact with the function layer 6F. Since the function layer 6F has a deeper CBM than the inorganic matrix material MX and has high carrier transport properties, the light-emission characteristics (voltage-luminance characteristics) can be exhibited at a further lower voltage. Furthermore, since the inorganic matrix material MX is not interposed between the exposed quantum dots QD and the function layer 6F, the electron injection barrier is lowered, and the light-emission characteristics (voltage-luminance characteristics) can be exhibited at a further lower voltage. The configuration in FIG. 3 can be formed by, for example, forming the light-emitting layer 5 including the inorganic matrix material MX and then etching the vicinity of the upper face of the inorganic matrix material MX to expose part of the respective quantum dots QD in the vicinity of the upper face from the inorganic matrix material MX. As an example, when a chemical bath deposition (CBD) method in which an inorganic layer (function layer 6F) is grown in an alkaline aqueous solution is used, the etching of the inorganic matrix material MX and the growth of the function layer 6F can be carried out in the same process of a simple aqueous solution system. In the function layer 6F formed by the CBD method, OH groups (hydroxyl groups) are bonded with metal elements to terminate dangling bonds of the metal elements, whereby non-emitting transition of carriers in the function layer 6F can be suppressed. Furthermore, since the function layer 6F can be obtained in which mobility as one of the indices of carrier transport properties is significantly high to be larger than 1.0[cm²/Vs], the carriers can be transported at a lower voltage.

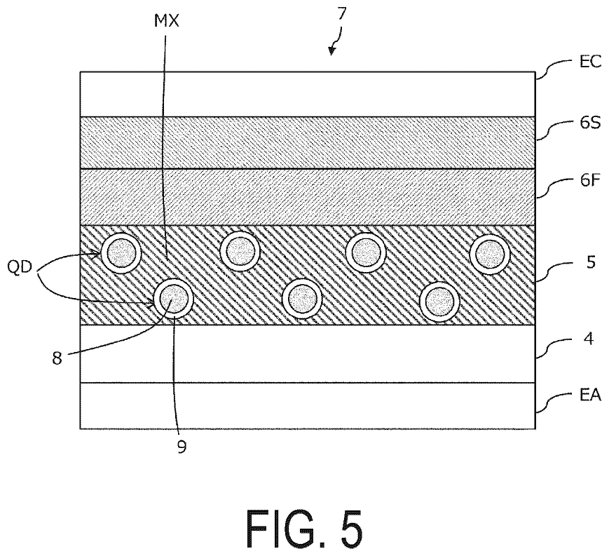

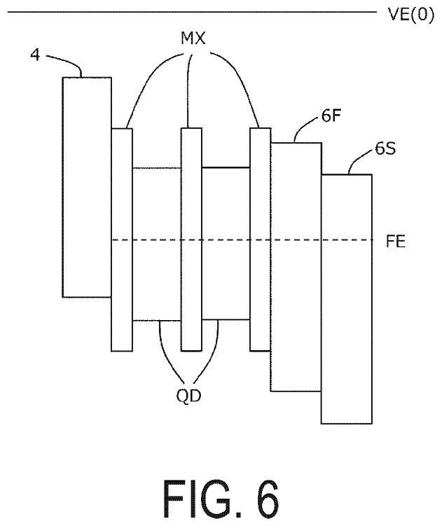

FIG. 5 is a cross-sectional view illustrating another configuration of the light-emitting element according to the embodiment. FIG. 6 is an example of a schematic band diagram of the light-emitting element illustrated in FIG. 5. As illustrated in FIGS. 5 and 6, the function layer 6F may be a first electron transport layer, a second electron transport layer 6S may be disposed between the first electron transport layer 6F and the cathode EC, and the second electron transport layer 6S may be formed of constituent elements identical to those of the first electron transport layer 6F and have a different composition ratio from that of the first electron transport layer 6F. The CBM of the second electron transport layer 6S is deeper than that of the first electron transport layer 6F. By the CBM of the first electron transport layer 6F and the CBM of the second electron transport layer 6S being configured to form a step-like potential, the voltage for injecting carriers into the quantum dots QD can be made lower than that in the case of a single layer of the electron transport layer 6F.

In FIG. 5 and FIG. 6, by controlling the Fermi levels of the first and second electron transport layers 6F and 6S, a step-like potential is formed to make it possible to lower the voltage for carrier injection (electron injection). For example, the first electron transport layer 6F may be zinc sulfide represented by ZnₓS (x>1), and the second electron transport layer 6S may be zinc sulfide represented by Zn_{z}S (z>x); the first electron transport layer 6F may be zinc selenide represented by ZnₓSe (x>1), and the second electron transport layer 6S may be zinc selenide represented by Zn_{z}Se (z>x).

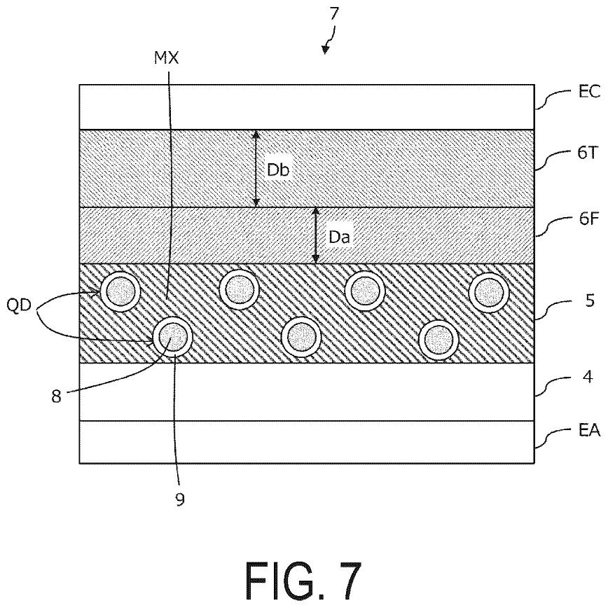

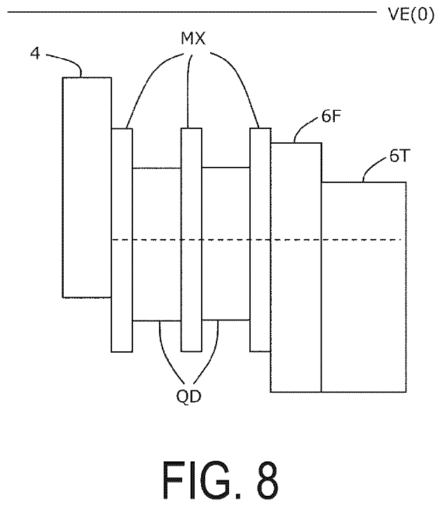

FIG. 7 is a cross-sectional view illustrating another configuration of the light-emitting element according to the embodiment. FIG. 8 is an example of a schematic band diagram of the light-emitting element illustrated in FIG. 7. As illustrated in FIGS. 7 and 8, the function layer 6F may be the first electron transport layer, a second electron transport layer 6T may be disposed between the first electron transport layer 6F and the cathode EC, and a relation of S1/Da³≥ S2/Db³ may be satisfied, where S1 is electron mobility of the first electron transport layer 6F and Da is a thickness thereof, and S2 is electron mobility of the second electron transport layer 6T and Db is a thickness thereof.

In order to enhance the external luminous efficiency (EQE) of the light-emitting element 7, it is necessary to improve the carrier injection efficiency with which electrons and holes are injected into quantum dots QD. Furthermore, in a case where excessive carriers are generated, such carriers do not contribute to light emission recombination, and therefore it is effective to adjust carrier balancing, which is the ratio of the quantities of injected electrons and holes.

Then, as in FIG. 7, by layering the first electron transport layer 6F and the second electron transport layer 6T with mobility lower than that of the first electron transport layer 6F, a bottleneck in the quantity of injected electrons is intentionally created, and the carrier balancing can be adjusted to the hole side generally having a small quantity of carrier injection. The quantity of carrier injection is calculated by solving Poisson's equation taking the dielectric constant, mobility, carrier density, and film thickness of the ETL material into consideration. However, when the layer thickness is equal to or less than 100 nm and the mobility is equal to or less than 1.0[cm²/Vs], the space charge limited current (SCLC) is more dominant than the ohmic current, and the quantity of carrier injection is described based on Child's law, where the dielectric constant, mobility, film thickness, and voltage are taken as parameters. In a case where the dielectric constants of the first and second electron transport layers 6F and 6T are identical, when the quantities of electrons injected at the same voltage are compared, the following can be described: when a relation of S1/Da³≥S2/Db³ is satisfied, where S1 is the electron mobility of the first electron transport layer 6F and Da is the thickness thereof, and S2 is the electron mobility of the second electron transport layer 6T and Db is the thickness thereof, an electron injection bottleneck can be intentionally created to improve the carrier balancing and consequently improve the external luminous efficiency (EQE).

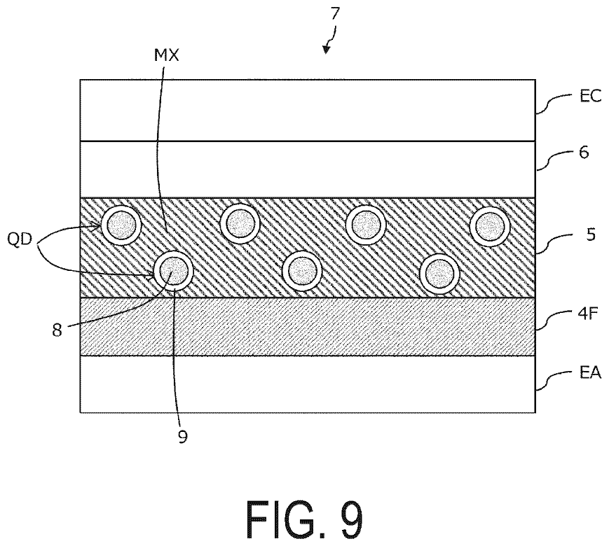

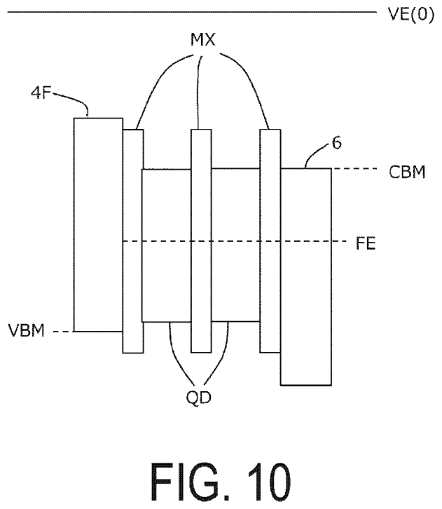

FIG. 9 is a cross-sectional view illustrating another configuration of the light-emitting element according to the embodiment. FIG. 10 is an example of a schematic band diagram of the light-emitting element illustrated in FIG. 9. As illustrated in FIGS. 9 and 10, a function layer 4F (hole transport layer: HTL) formed of constituent elements identical to those of the inorganic matrix material MX and having a different composition ratio from that of the inorganic matrix material MX is disposed between the light-emitting layer 5 and the anode EA. The VBM of the function layer 4F may be deeper than that of the plurality of quantum dots QD. The VBM of the function layer 4F may be shallower than that of the inorganic matrix material MX.

Zinc sulfide and zinc selenide exhibit p-type conductivity in which a zinc defect serves as an acceptor when there is a shortage of zinc as an atomic composition ratio. Accordingly, the function layer 4F (HTL) may have a smaller zinc composition ratio than the inorganic matrix material MX. In a case where the function layer 4F (HTL) is zinc sulfide represented by ZnₓS (0<x<1), for example, the inorganic matrix material MX is zinc sulfide represented by Zn_{y}S (x<y). In a case where the function layer 4F (HTL) is zinc selenide represented by ZnₓSe (0<x<1), the inorganic matrix material MX is zinc selenide represented by Zn_{y}Se (x<y).

In the light-emitting element 7, since the inorganic matrix material MX and the function layer 4F (HTL) formed of the identical constituent elements are subjected to homo junction, a potential barrier between the function layer 4F and the inorganic matrix material MX becomes small. Thus, hole injection from the function layer 4F into the light-emitting layer 5 is facilitated, and light emission power efficiency (power consumption-luminance characteristics of the light-emitting element) is improved. In addition, since the VBM of the function layer 4F is deeper than that of the plurality of quantum dots QD, a hole injection barrier from the function layer 4F (hole transport layer) into the light-emitting layer 5 is reduced, and the light emission power efficiency is enhanced.

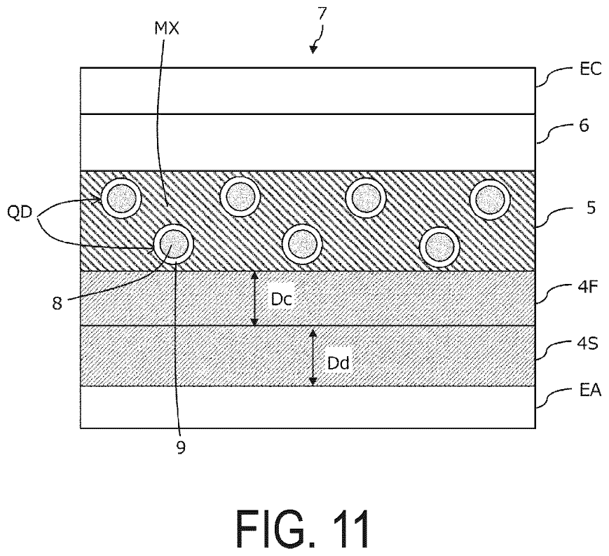

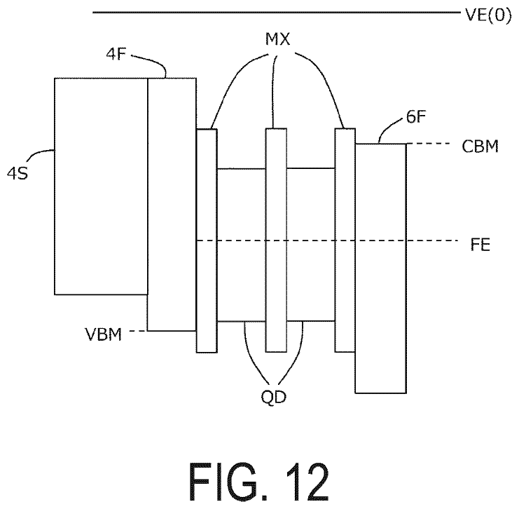

FIG. 11 is a cross-sectional view illustrating another configuration of the light-emitting element according to the embodiment. FIG. 12 is an example of a schematic band diagram of the light-emitting element illustrated in FIG. 11. As illustrated in FIGS. 11 and 12, the function layer 4F may be a first hole transport layer, and a second hole transport layer 4S may be disposed between the first hole transport layer 4F and the anode EA. When the hole mobility of the first hole transport layer 4F is taken as S3 and the thickness thereof is taken as Dc, and the hole mobility of the second hole transport layer 4S is taken as S4 and the thickness thereof is taken as Dd, a relation of S3/Dc³≥S4/Dd³ may be satisfied. This makes it possible to intentionally create a hole injection bottleneck, and improve the carrier balancing and consequently improve the external luminous efficiency (EQE).

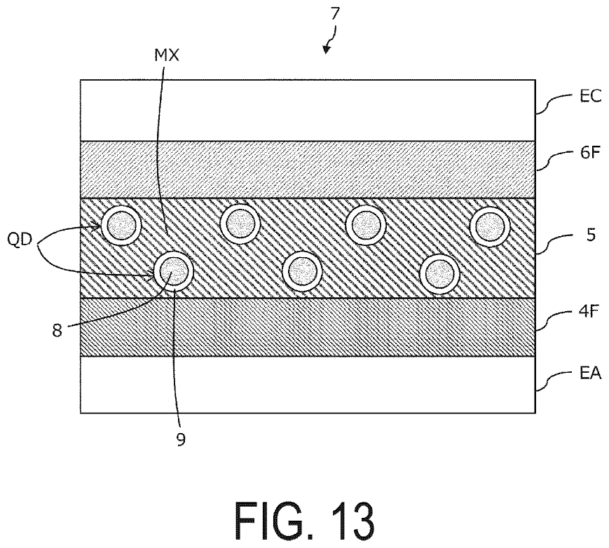

FIG. 13 is a cross-sectional view illustrating another configuration of the light-emitting element according to the embodiment. As illustrated in FIG. 13, the function layer 4F (HTL) formed of the identical constituent elements to those of the inorganic matrix material MX and having a different composition ratio from that of the inorganic matrix material MX may be disposed between the anode EA and the light-emitting layer 5, and the function layer 6F (ETL) formed of the identical constituent elements to those of the inorganic matrix material MX and having a different composition ratio from that of the inorganic matrix material MX may be disposed between the cathode EC and the light-emitting layer 5. The inorganic matrix material MX and the function layers 4F, 6F may be zinc chalcogenide (zinc sulfide, zinc selenide, or the like), the function layer 6F (ETL) may have a higher zinc composition ratio than the inorganic matrix material MX, and the function layer 4F (HTL) may have a lower zinc composition ratio than the inorganic matrix material MX. This makes it possible to respectively reduce the electron injection barrier and hole injection barrier by the step-like potential.

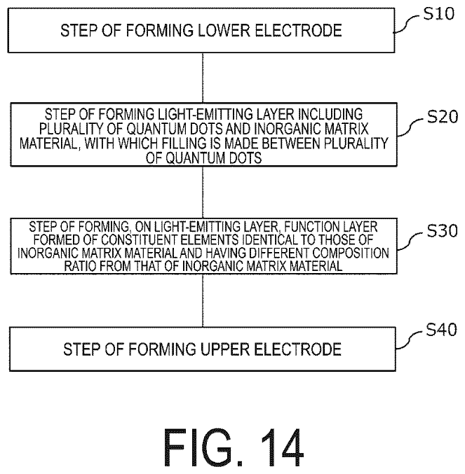

FIG. 14 is a flowchart illustrating a method for manufacturing the light-emitting element according to the embodiment. As illustrated in FIGS. 1 and 14, the method for manufacturing the light-emitting element according to the embodiment includes: a step S10 of forming an lower electrode (e.g., the anode EA); a step S20 of forming the light-emitting layer 5 including the plurality of quantum dots QD and the inorganic matrix material MX, with which filling is made between the quantum dots QD; a step S30 of forming, on the light-emitting layer 5, the function layer 6F formed of constituent elements identical to those of the inorganic matrix material MX and having a different composition ratio from that of the inorganic matrix material MX; and a step S40 of forming an upper electrode (e.g., the cathode EC).

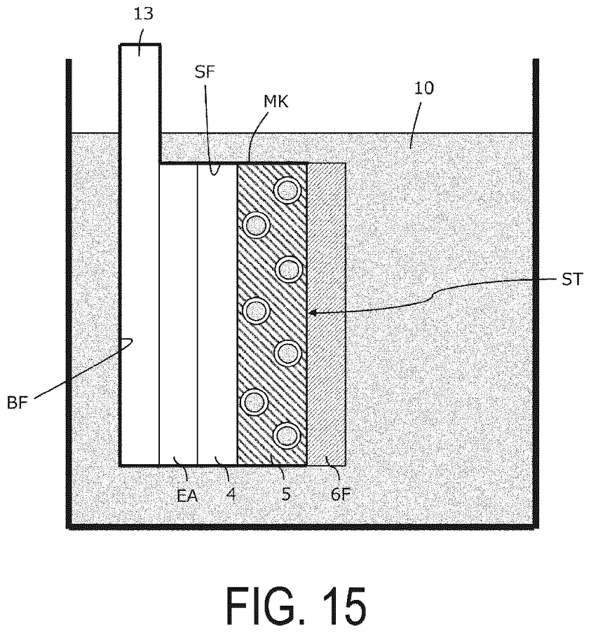

FIG. 15 is a schematic cross-sectional view illustrating a method for forming a function layer by using the CBD method. For example, by immersing a layered body ST including a substrate 13, the anode EA, the hole transport layer 4, and the light-emitting layer 5 in an alkaline aqueous solution 10 containing a metal source and a chalcogen source at a predetermined temperature for a predetermined time in a state where a lower face BF and side surfaces SF of the layered body ST are covered with a mask MK, the function layer 6F can be grown on the layered body ST (so as to be in contact with the light-emitting layer 5).

For example, when zinc sulfate (ZnSO₄) as a zinc source is mixed to have a concentration of 0.16 mol/L, ammonia as an alkali source is mixed to have a concentration of 7.5 mol/L, and thiourea as a sulfur source is mixed to have a concentration of 0.6 mol/L, the alkaline aqueous solution 10 with pH 11 is obtained. The temperature of the alkaline aqueous solution 10 is adjusted to be 80° C., and the layered body ST is immersed therein for 15 minutes, thereby forming a zinc sulfide thin film (including oxygen atoms and hydroxyl groups) having a thickness of 100 nm.

The quantum dot QD used in the present embodiment may be a dot having a maximum width of 100 nm or less, and may have a spherical shape or a non-spherical shape. The shape of the quantum dot QD is not limited to a spherical three-dimensional shape (circular cross-sectional shape) as long as the shape satisfies the maximum width mentioned above. The maximum width may be 1.0 nm or more. The shape may be, for example, a polygonal cross-sectional shape, a rod-shaped three-dimensional shape, a branch-shaped three-dimensional shape, or a three-dimensional shape having unevenness on the surface, or a combination thereof. The quantum dot QD may be composed of a semiconductor material and may be an inorganic semiconductor nanocrystal. The semiconductor material may have a certain band gap and may be a material in which electroluminescence occurs. The wavelength region of electroluminescence may be any of a red region, a green region, and a blue region.

The quantum dot QD may include at least one of a crystal of a group II-VI semiconductor such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, or HgTe; a crystal of a group III-V semiconductor such as GaAs, GaP, InN, InAs, InP, or InSb; a chalcogenide compound crystal; a perovskite compound crystal; and a crystal of a group IV semiconductor such as Si or Ge. Note that the group II-VI compound refers to a compound including a group II element and a group VI element, and the group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃. Examples of the constituent element X include at least one kind selected from the group consisting of Cl, Br, and I.

Here, the numbering of groups of an element by using Roman numerals is numbering based on the old International Union of Pure and Applied Chemistry (IUPAC) system or old Chemical Abstracts Service (CAS) system, and the numbering of groups of an element by using Arabic numerals is numbering based on the current IUPAC system.

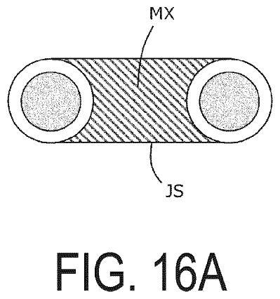

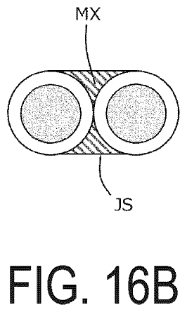

FIG. 16A and FIG. 16B are each a schematic cross-sectional view illustrating a forming example of an inorganic matrix material. As illustrated in FIG. 16A and FIG. 16B, the inorganic matrix material MX fills a region (space) JS between two quantum dots QD adjacent to each other. The region JS is filled with the inorganic matrix material MX. The region JS may be a region surrounded by two straight lines (external common tangents) in contact with the outer peripheries of the two quantum dots QD adjacent to each other and the two quantum dots QD adjacent to each other in a cross section of the light-emitting layer 5. As illustrated in FIG. 16B, even when two adjacent quantum dots are close to each other, the region JS exists and the region JS is filled with the inorganic matrix material MX. When it is recognized that the inorganic matrix material fills the space between at least two quantum dots QD, the inorganic matrix material is considered to be working as the inorganic matrix material filling the space between the plurality of quantum dots. That is, when it is recognized that the region (space) JS between two adjacent quantum dots QD is filled with the inorganic matrix material MX, it can be said that space between the plurality of quantum dots QD is filled with the inorganic matrix material MX.

There is also a case of “holding” as another example of “filling” or “filled with”. Two adjacent quantum dots QD may be held by the presence of the inorganic matrix material MX in the region JS, or two quantum dots QD may be held by at least part of the region JS being filled with the inorganic matrix material MX, for example.

The inorganic matrix material MX contains an inorganic material (inorganic substance) as a main component. The inorganic matrix material MX may be a constituent element of the light-emitting layer including the plurality of quantum dots QD. The inorganic matrix material MX may be a member that is composed of an inorganic substance (e.g., an inorganic semiconductor) and includes and holds other objects, and can be referred to as a base material, a parent material, or a filler. The inorganic matrix material MX may be solid at room temperature. The inorganic matrix material MX may include therein the plurality of quantum dots QD. The inorganic matrix material MX may fill a region (space) other than the plurality of quantum dots QD or between the plurality of quantum dots QD in the light-emitting layer (quantum dot layer). The inorganic matrix material MX may bury a region (space) other than the plurality of quantum dots QD in the light-emitting layer. The inorganic matrix material MX may partially or completely fill the space between the plurality of quantum dots QD. The plurality of quantum dots QD may be embedded in the inorganic matrix material MX at intervals. The inorganic matrix material MX may indicate a portion of the light-emitting layer excluding the plurality of quantum dots QD.

The inorganic matrix material MX may completely or incompletely fill a region (space) other than a quantum dot group in the light-emitting layer. Here, three or more quantum dots QD are collectively referred to as a quantum dot group. In the disclosure, it is sufficient that the structure of the inorganic matrix material MX or the like is recognized to have a desired configuration across a width of approximately 100 nm when the cross section of the light-emitting layer 5 is observed, and the desired configuration is not needed to be observed over the entire light-emitting layer 5 unless specifically noted or being inconsistent. The inorganic matrix material MX in the quantum dot layer may be formed as a continuous film having an area equal to or larger than 1000 nm² along a plane direction orthogonal to the layer thickness direction. The continuous film means a film not partitioned by a material other than a material constituting the continuous film in one plane. The continuous film may be in the form of an integrated film connected without interruption by chemical bonding of the inorganic matrix material MX.

The outer periphery of the light-emitting layer may be constituted of the inorganic matrix material MX, and the quantum dots QD may be configured to be located away from the outer edge. The outer edge of the light-emitting layer does not need to be formed of only the inorganic matrix material MX, and the quantum dots QD may be partially exposed from the inorganic matrix material MX.

The inorganic matrix material MX may be the identical material to that of the shell included in each of the plurality of quantum dots QD. When the shell of the quantum dot QD and the inorganic matrix material MX cannot be distinguished from each other, the shell may be regarded as part of the inorganic matrix material MX. The inorganic matrix material MX may contain a substance different from the inorganic compound (zinc sulfide, zinc selenide, or the like) as the main component, as an additive, an impurity, or a residue. When the light-emitting layer including the inorganic matrix material MX is analyzed, the contained carbon atoms may be equal to or less than 5 at %.

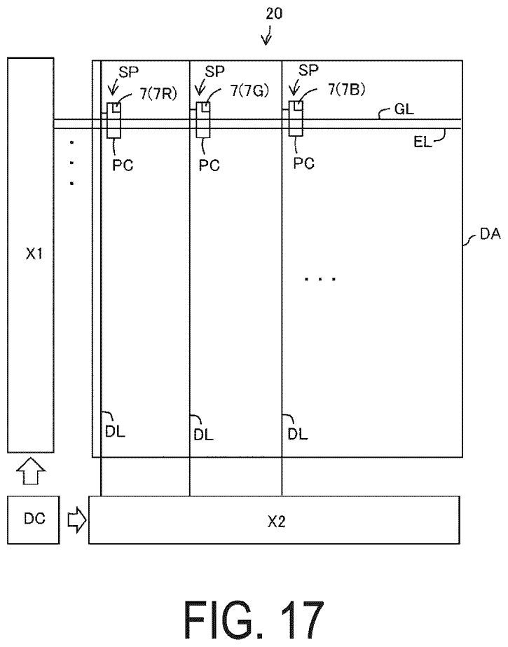

FIG. 17 is a schematic diagram illustrating an example of a configuration of a display device according to the present embodiment. As illustrated in FIG. 17, a display device 20 includes a display portion DA including a plurality of subpixels SP, a first driver X1 and a second driver X2 configured to drive the plurality of subpixels SP, and a display control unit DC configured to control the first driver X1 and the second driver X2. Each subpixel SP includes the light-emitting element 7 and a pixel circuit PC connected to the light-emitting element 7. The pixel circuit PC may be connected to a scanning signal line GL, a data signal line DL, and a light emission control line EL. The scanning signal line GL and the light emission control line EL may be connected to the first driver X1, and the data signal line DL may be connected to the second driver X2.

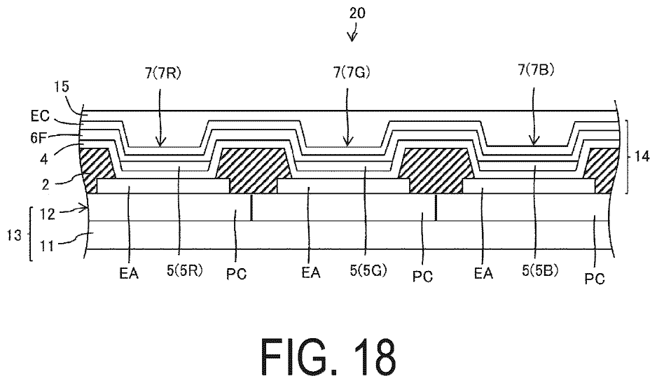

FIG. 18 is a cross-sectional view illustrating an example of a configuration of the display device according to the present embodiment. The display device 20 may include the substrate 13, a light-emitting element layer 14, and a sealing layer 15. The substrate 13 may be a pixel circuit substrate including a support substrate 11 and a pixel circuit layer 12. For the support substrate 11, a glass substrate, a resin substrate, or the like can be used. The support substrate 11 may have flexibility. The pixel circuit layer 12 includes a plurality of the pixel circuits PC arranged in a matrix shape, for example. The pixel circuit PC may include: a pixel capacitance into which a gray scale signal is written, a transistor that controls a current value of the light-emitting element 7 in accordance with the gray scale signal, a transistor connected to the scanning signal line GL and the data signal line DL, and a transistor connected to the light emission control line EL.

As illustrated in FIG. 18, the light-emitting element layer 14 may include the anode EA, an edge cover film 2 covering an edge of the anode EA, the hole transport layer 4, the light-emitting layer 5, the function layer 6F, and the cathode EC in this order from the substrate 13 side. The function layer 6F may be the electron transport layer. The light-emitting element layer 14 may include a light-emitting element 7R (7) including a light-emitting layer 5R (5) configured to emit red light, a light-emitting element 7G (7) including a light-emitting layer 5G (5) configured to emit green light, and a light-emitting element 7B (7) including a light-emitting layer 5B (5) configured to emit blue light. The cathode EC may be located on a light-output side. The sealing layer 15 includes an inorganic insulating film such as a silicon nitride film or a silicon oxide film, and prevents foreign matter (water, oxygen, or the like) from entering the light-emitting element layer 14.

The embodiments described above are for the purpose of illustration and description and are not intended to be limiting. It will be apparent to those skilled in the art that many variations will be possible in accordance with these examples and descriptions.

### Reference Signs List

4 Hole transport layer
4F Function layer (hole transport layer)
5 Light-emitting layer
6 Electron transport layer
6F Function layer (electron transport layer)
7 Light-emitting element
8 Core
9 Shell
EA Anode
EC Cathode
QD Quantum dot
MX Inorganic matrix material

1. A light-emitting element, comprising:
an anode and a cathode;
a light-emitting layer disposed between the anode and the cathode, the light-emitting layer including a plurality of quantum dots and an inorganic matrix material; and
a function layer disposed between the anode and the cathode to be adjacent to the light-emitting layer, the function layer being formed of constituent elements identical to constituent elements of the inorganic matrix material and having a composition ratio different from a composition ratio of the inorganic matrix material.

2. The light-emitting element according to claim 1,
wherein each of the plurality of quantum dots includes a core and a shell, the shell:
formed of constituent elements identical to the constituent elements of the inorganic matrix material; and
having a composition ratio different from the composition ratio of the inorganic matrix material or having the composition ratio identical to the composition ratio of the inorganic matrix material.

3. The light-emitting element according to claim 1,
wherein at least one of the plurality of quantum dots is in contact with the function layer.

4. The light-emitting element according to claim 1,
wherein each of the function layer and the inorganic matrix material includes a metal element and a nonmetal element.

5. The light-emitting element according to claim 4,
wherein the metal element is zinc, and the nonmetal element is sulfur or selenium.

6. The light-emitting element according to claim 5,
wherein the function layer includes a hydroxyl group.

7. (canceled)

8. The light-emitting element according to claim 1,
wherein the function layer is disposed between the light-emitting layer and the cathode.

9. The light-emitting element according to claim 8,
wherein a conduction band minimum level (CBM) of the function layer is shallower than a CBM of the plurality of quantum dots.

10. The light-emitting element according to claim
wherein a conduction band minimum level (CBM) of the function layer is deeper than a CBM of the inorganic matrix material.

11. The light-emitting element according to claim 8,
wherein each of the function layer and the inorganic matrix material includes zinc and sulfur or selenium, and
a composition ratio of zinc is larger in the function layer than in the inorganic matrix material.

12. The light-emitting element according to claim 2,
wherein a material of the inorganic matrix material and a material of the shell are identical.

13. The light-emitting element according to claim 8,
wherein the function layer is a first electron transport layer,
a second electron transport layer is disposed between the first electron transport layer and the cathode, and
the second electron transport layer is formed of constituent elements identical to constituent elements of the first electron transport layer and has a composition ratio different from a composition ratio of the first electron transport layer.

14. The light-emitting element according to claim 13,
wherein a conduction band minimum level (CBM) of the second electron transport layer is deeper than a CBM of the first electron transport layer.

15. The light-emitting element according to claim 8,
wherein the function layer is a first electron transport layer,
a second electron transport layer is disposed between the first electron transport layer and the cathode, and
a relation of S1/Da³≥S2/Db³ is satisfied, where S1 is an electron mobility of the first electron transport layer and Da is a thickness of the first electron transport layer, and S2 is an electron mobility of the second electron transport layer and Db is a thickness of the second electron transport layer.

16. The light-emitting element according to claim 1,
wherein the function layer is disposed between the light-emitting layer and the anode.

17. The light-emitting element according to claim 16,
wherein a valence band maximum level (VBM) of the function layer is deeper than a VBM of the plurality of quantum dots.

18. The light-emitting element according to claim 16,
wherein a valence band maximum level (VBM) of the function layer is shallower than a VBM of the inorganic matrix material.

19. The light-emitting element according to claim 16,
wherein the function layer and the inorganic matrix material include zinc and one of sulfur or selenium, and
a composition ratio of zinc is smaller in the function layer than in the inorganic matrix material.

20. The light-emitting element according to claim 16,
wherein the function layer is a first hole transport layer,
a second hole transport layer is disposed between the first hole transport layer and the anode, and
a relation of S3/Dc³≥S4/Dd³ is satisfied, where S3 is a hole mobility of the first hole transport layer and Dc is a thickness of the first hole transport layer, and S4 is a hole mobility of the second hole transport layer and Dd is a thickness of the second hole transport layer.

21. (canceled)

22. A display device comprising:
the light-emitting element according to claim 1.

23. (canceled)

24. (canceled)

25. (canceled)
